(19) United States
(12) Patent Application Publication
(10) Pub. No.: US 2026/0277107 A1
(43) Pub. Date: Sep. 17, 2026

(54) SUBSTRATE TREATMENT APPARATUS AND SUBSTRATE TREATMENT METHOD

(71) Applicant: Tokyo Electron Limited, Tokyo (JP)

(72) Inventors: Yasunobu IWAMOTO, Koshi City, Kumamoto (JP); Hiroyuki FUJII, Koshi City, Kumamoto (JP)

(21) Appl. No.: 19/167,747

(22) PCT Filed: Mar. 19, 2024
(86) PCT No.: PCT/JP2024/010712

§ 371 Date: Sep. 22, 2025

(30) Foreign Application Priority Data
Mar. 30, 2023 (JP) 2023-055445

(51) Int. Cl. G03F 7/42; H10P 76/40

(52) U.S. Cl. CPC G03F 7/422; H10P 76/4085

(57) ABSTRACT

A substrate treatment apparatus for treating a substrate, includes: a substrate holder configured to hold and rotate a substrate on which a coating film containing metal is formed; a first treatment solution supplier configured to supply a first treatment solution to a front surface of the substrate; a second treatment solution supplier configured to supply a second treatment solution to the front surface of the substrate; a third treatment solution supplier configured to supply a third treatment solution to the front surface of the substrate; and a controller, wherein the controller is configured to execute: a first step of supplying the first treatment solution from the first treatment solution supplier to a first width region from an end portion of the substrate while rotating the substrate to remove the coating film; a second step of supplying, after the first step, the second treatment solution from the second treatment solution supplier to a second width region having a width narrower than the first width region from the end portion of the substrate while rotating the substrate to remove the metal remaining in the second width region; and a third step of supplying, after the second step, the third treatment solution from the third treatment solution supplier to a third width region having a width narrower than the first width region and wider than the second width region from the end portion of the substrate while rotating the substrate to wash away the second treatment solution remaining in the third width region.

### TECHNICAL FIELD

This disclosure relates to a substrate treatment apparatus and a substrate treatment method.

### BACKGROUND ART

Patent Document 1 discloses a coating film removing apparatus for removing, by a removing solution, a peripheral edge portion of a coating film formed by supplying a coating solution to a front surface of a circular substrate.

### PRIOR ART DOCUMENT

### Patent Document

Patent Document 1: Japanese Laid-open Patent Publication No. 2018-121045

### SUMMARY OF THE INVENTION

### Problems to be Solved by the Invention The technique according to this disclosure suitably removes a peripheral portion of a coating containing metal formed on a substrate.

### Means for Solving the Problems

An aspect of this disclosure is a substrate treatment apparatus for treating a substrate, including: a substrate holder configured to hold and rotate a substrate on which a coating film containing metal is formed; a first treatment solution supplier configured to supply a first treatment solution to a front surface of the substrate; a second treatment solution supplier configured to supply a second treatment solution to the front surface of the substrate; a third treatment solution supplier configured to supply a third treatment solution to the front surface of the substrate; and a controller, wherein the controller is configured to execute: a first step of supplying the first treatment solution from the first treatment solution supplier to a first width region from an end portion of the substrate while rotating the substrate to remove the coating film; a second step of supplying, after the first step, the second treatment solution from the second treatment solution supplier to a second width region having a width narrower than the first width region from the end portion of the substrate while rotating the substrate to remove the metal remaining in the second width region; and a third step of supplying, after the second step, the third treatment solution from the third treatment solution supplier to a third width region having a width narrower than the first width region and wider than the second width region from the end portion of the substrate while rotating the substrate to wash away the second treatment solution remaining in the third width region.

### Effect of the Invention

According to this disclosure, it is possible to suitably remove a peripheral portion of a coating containing metal formed on a substrate.

### BRIEF DESCRIPTION OF THE DRAWINGS

FIG. 1 is a side view schematically illustrating the outline of a configuration of a coating film forming apparatus according to an embodiment.

FIG. 2 is a plan view schematically illustrating the outline of the configuration of the coating film forming apparatus in FIG. 1.

FIG. 3 illustrates an appearance of applying a metal-containing resist film to a front surface of a wafer in a coating film forming method according to an embodiment, (a) is a perspective view, (b) is an explanatory view schematically illustrating a part of a side cross section, and (c) is a plan view of a part of an end portion of the wafer.

FIG. 4 illustrates an appearance of execution of a first step in the coating film forming method according to the embodiment, (a) is a perspective view, (b) is an explanatory view schematically illustrating a part of a side cross section, and (c) is a plan view of a part of the end portion of the wafer.

FIG. 5 illustrates an appearance of execution of a second step in the coating film forming method according to the embodiment, (a) is a perspective view, (b) is an explanatory view schematically illustrating a part of a side cross section, and (c) is a plan view of a part of the end portion of the wafer.

FIG. 6 illustrates an appearance of execution of a third step in the coating film forming method according to the embodiment, (a) is a perspective view, (b) is an explanatory view schematically illustrating a part of a side cross section, and (c) is a plan view of a part of the end portion of the wafer.

FIG. 7 is an explanatory view illustrating a discharge angle in plan view of a treatment solution supply nozzle to the wafer in the coating film forming apparatus according to the embodiment.

FIG. 8 is an explanatory view illustrating a discharge angle in side view of the treatment solution supply nozzle to the wafer in the coating film forming apparatus according to the embodiment.

FIG. 9 is an explanatory view illustrating in plan view an arrangement situation when three treatment solution supply nozzles are arranged on the front surface side of the wafer.

FIG. 10 is an explanatory view illustrating in plan view the arrangement situation of rear surface nozzles arranged on a rear surface side of the wafer in the case having the arrangement in FIG. 9.

### EMBODIMENTS FOR CARRYING OUT INVENTION

In a photolithography step in a manufacturing process of a semiconductor device, coating films such as an anti-reflection film and a resist film are formed, for example, on a treatment object such as a semiconductor wafer (hereinafter, referred to as a “wafer”) as a substrate. In this case, for example, when forming the resist film, a spin coating method is often employed which supplies a resist solution to the wafer from above a central portion of the wafer and rotates the wafer to diffuse the resist solution on the wafer over the entire wafer surface.

In the spin coating method, the resist solution on the wafer spreads down to a side end portion of the wafer. Therefore, for the resist film formed after the application of the resist solution, in order to remove the resist film in a region of a constant width from the end portion of the wafer, for example, an organic solvent such as a thinner for dissolving the resist film is supplied to the region while rotating the wafer to remove the resist film as in the technique disclosed in Patent Document 1.

In recent years, in order to form a finer pattern, it is proposed to form a coating film containing metal (hereinafter, referred to as a “metal-containing coating film”) on the substrate such as the wafer.

In the case of removing the metal-containing coating film (coating), if using only the organic solvent such as a thinner for dissolving the coating film itself, a metal component contained in the dissolved coating film remains on the front surface at a peripheral portion of the wafer to adversely affect the subsequent process or become a cause of cross-contamination.

The technique according to this disclosure suitably removes a metal-containing coating film from a peripheral portion of a substrate on which a metal-containing coating film (coating) is formed. Hereinafter, a configuration of the substrate treatment apparatus according to this embodiment will be explained while referring to the drawings. Note that in this description, components having substantially the same functional configurations are denoted by the same reference numerals to omit overlapped explanation.

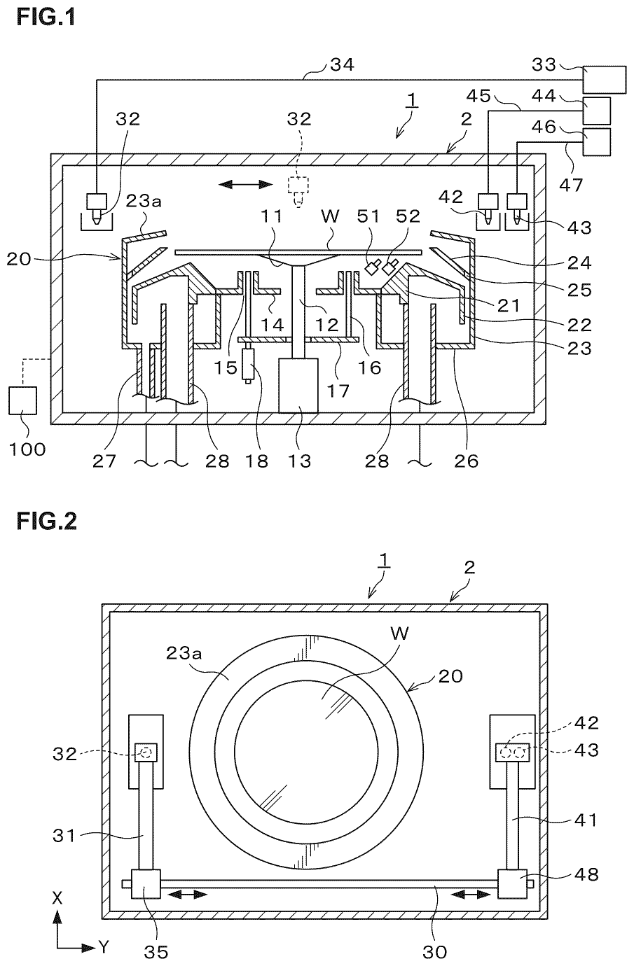

FIG. 1 is an explanatory view schematically illustrating from a side the outline of a configuration of a coating film forming apparatus 1 configured as an example of a substrate treatment apparatus, and FIG. 2 is an explanatory view schematically illustrating the same from a plane.

As illustrated in FIG. 1 and FIG. 2, the coating film forming apparatus 1 includes, in a treatment container 2, a spin chuck 11 being a substrate holder which vacuum-sucks a rear surface central portion of a wafer W as a substrate to horizontally hold the wafer W. The spin chuck 11 is connected to a rotation drive mechanism 13 via a shaft part 12 and rotates around the vertical axis by the rotation drive mechanism 13.

On a lower side of the spin chuck 11, a circular plate 14 is provided in a manner to surround the shaft part 12 via a gap. The circular plate 14 is formed with through holes 15 at three locations in a circumferential direction, and a raising and lowering pin 16 can be inserted into each of the through holes 15. These raising and lowering pins 16 are supported by a raising and lowering plate 17. The raising and lowering plate 17 is freely raised and lowered by a raising and lowering mechanism 18. By the raising and lowering of the raising and lowering mechanism 18, the raising and lowering pins 16 can lift up the wafer W, which has been released from the suction-holding, from the top of the spin chuck 11, or mount the wafer W received from a transfer apparatus (not illustrated) on the spin chuck 11.

In the treatment container 2 of the coating film forming apparatus 1, a cup body 20 is provided in a manner to surround the spin chuck 11. The cup body 20 is configured to receive drainage scattered or dropped from the rotating wafer W and drain the drainage to the outside of the coating film forming apparatus 1.

In more detail, the cup body 20 has a mountain-shaped guide part 21 having a cross-sectional shape in a mountain ring shape which is provided around the above circular plate 14, and has an annular vertical wall 22 which is provided in a manner to extend downward from an outer peripheral edge of the mountain-shaped guide part 21. The mountain-shaped guide part 21 guides the liquid dropped from the wafer W to below the outside of the wafer W.

On the outside of the mountain-shaped guide part 21, a cylindrical part 23 which is vertical in a manner to surround the mountain-shaped guide part 21 and an upper guide part 24 which extends diagonally from an upper edge of the cylindrical part 23 toward an inner upper side are provided. The upper guide part 24 is provided with a plurality of openings 25 in the circumferential direction. Further, an upper end portion of the cylindrical part 23 extends to above the spin chuck 11, and its end inner edge is provided with an inclined body 23a extending to an inner upper side.

On a lower side of the cylindrical part 23, a ring-shaped liquid receiver 26 having a cross-section in a recessed shape is formed below the mountain-shaped guide part 21 and the cylindrical part 23. To an outer peripheral side of the liquid receiver 26, a drainage path 27 is connected. Further, on an inner peripheral side of the drainage path 27 at the liquid receiver 26, two exhaust pipes 28 are provided.

Further, as illustrated in FIG. 2, a rail 30 extending along a Y-direction (right-left direction in FIG. 2) is formed on an X-direction negative direction (lower direction in FIG. 2) side of the cup body 20. The rail 30 is located, for example, from a Y-direction negative direction (left direction in FIG. 2) side outer position to a Y-direction positive direction (right direction in FIG. 2) side outer position of the cup body 20. On the rail 30, a first arm 31 and a second arm 41 are provided to be movable along the rail 30.

On the first arm 31, a resist solution supply nozzle 32 which supplies a metal-containing resist solution being a coating solution containing metal as a coating solution is supported. The metal-containing resist solution is supplied from a metal-containing resist solution supply source 33 via a supply path 34 to a resist solution supply nozzle 32. The first arm 31 is movable along the Y-direction on the rail 30 by a nozzle drive 35. Thus, the resist solution supply nozzle 32 is movable at least to above a central portion of the wafer W held on the spin chuck 11 inside the cup body 20. Further, the first arm 31 is freely raised and lowered by the nozzle drive 35 and thus can adjust the height of the resist solution supply nozzle 32.

On the second arm 41, a treatment solution supply nozzle 42 as a first treatment solution supplier which supplies a first treatment solution for dissolving and removing the coating film (for example, a zirconium oxide film) formed by the metal-containing resist solution, for example, an organic solvent such as PEGMEA (propylene glycol monomethyl ether acetate), and a treatment solution supply nozzle 43 as a second treatment solution supplier which supplies a second treatment solution for dissolving metal in the metal-containing coating film, for example, an acid thinner being an acidic treatment solution for dissolving the metal, are supported.

Further, in this embodiment, the treatment solution supply nozzle 42 also serves as a third treatment solution supplier. Specifically, the treatment solution supply nozzle 42 supplies a third treatment solution for cleaning a front surface of the wafer W, for example, PEGMEA after supplying the second treatment solution. In other words, the treatment solution supply nozzle 42 also serves as the first treatment solution supplier and the third treatment solution supplier, and the first treatment solution and the third treatment solution in this example are PEGMEA being the same solvent PG. The solvent PG being the first treatment solution and the third treatment solution is supplied from a supply source 44 via a supply path 45 to the treatment solution supply nozzle 42. The acid thinner being the second treatment solution is supplied from an acid thinner supply source 46 via a supply path 47 to the treatment solution supply nozzle 43.

The second arm 41 is movable on the rail 30 by a nozzle drive 48. Thus, the treatment solution supply nozzles 42, 43 can move to a width region being a constant region from at least an end portion above the wafer W in the cup body 20. Further, the second arm 41 is freely raised and lowered by the nozzle drive 48 and can adjust the heights of the treatment solution supply nozzles 42, 43.

Then, returning again to FIG. 1 for explanation, a first rear surface nozzle 51 as a fifth treatment solution supplier which supplies the PEGMEA and a second rear surface nozzle 52 as a fourth treatment solution supplier which supplies the acid thinner are arranged on the inner peripheral side of the mountain-shaped guide part 21. Supply directions (discharge directions) of liquid from the first rear surface nozzle 51 and the second rear surface nozzle 52 are directed diagonally outward from the lower surface side of the peripheral portion of the wafer W. The first rear surface nozzle 51 is located at a position closer to the center of the wafer W than the second rear surface nozzle 52.

The above coating film forming apparatus 1 is provided with at least one controller 100 as illustrated in FIG. 1. The controller 100 processes a computer-executable instruction which causes the coating film forming apparatus 1 to execute various processes described in this disclosure. The controller 100 can be constituted to control components of the coating film forming apparatus 1 so as to execute the various processes described herein. In one embodiment, part or whole of the controller 100 may be included in the coating film forming apparatus 1. The controller 100 may include a processor, a storage, and a communication interface. The controller 100 is implemented, for example, by a computer. The processor may be configured to read a program which provides a logic or routine enabling performance of various control operations from the storage and execute the read program to perform the various control operations. This can control, for example, the rotation speed of the spin chuck 11, the discharge positions, discharge flow rates, and discharge times of the treatment solution supply nozzles 42, 43, the discharge flow rates, discharge times, and so on of the liquid from the first rear surface nozzle 51 and the second rear surface nozzle 52.

This program may be stored in the storage in advance or acquired via a medium when required. The acquired program is stored in the storage, and read from the storage and executed by the processor. The medium may be various computer-readable storage media, or a communication line connected to the communication interface. The storage medium may be a transitory one or a non-transitory one. The processor may be a CPU (Central Processing Unit) or one or a plurality of circuits. The storage may include a RAM (Random Access Memory), a ROM (Read Only Memory), an HDD (Hard Disk Drive), an SDD (Solid State Drive), or a combination of them. The communication interface may communicate with the coating film forming apparatus 1 via the communication line such as a LAN (Local Area Network) or the like.

### Substrate Treatment Method

Next, a substrate treatment method using the above coating film forming apparatus 1 will be explained. In this example, a method of forming and treating a zirconium oxide film as the metal-containing coating film will be explained.

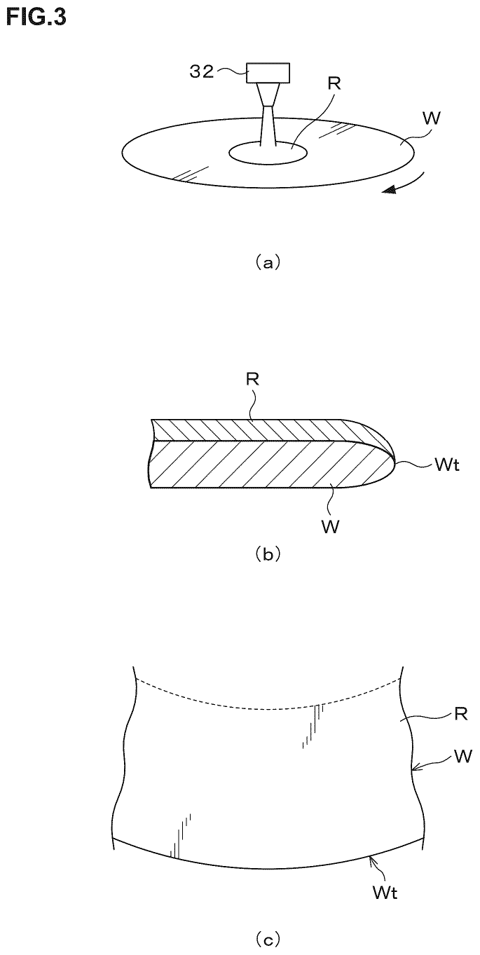

First, as illustrated in FIG. 3(a), the metal-containing resist solution for forming the zirconium oxide film is supplied from above the central portion of the wafer W held on the spin chuck 11, and the wafer W is rotated to diffuse the resist solution over the entire surface of the wafer W to form a metal-containing resist film R. For forming the metal-containing resist film R by the spin coating method, its rotation speed is, for example, 1400 rpm. This forms the metal-containing resist film R down to an end portion Wt on the side surface of the wafer Was illustrated in FIG. 3(b), (c).

### First Step

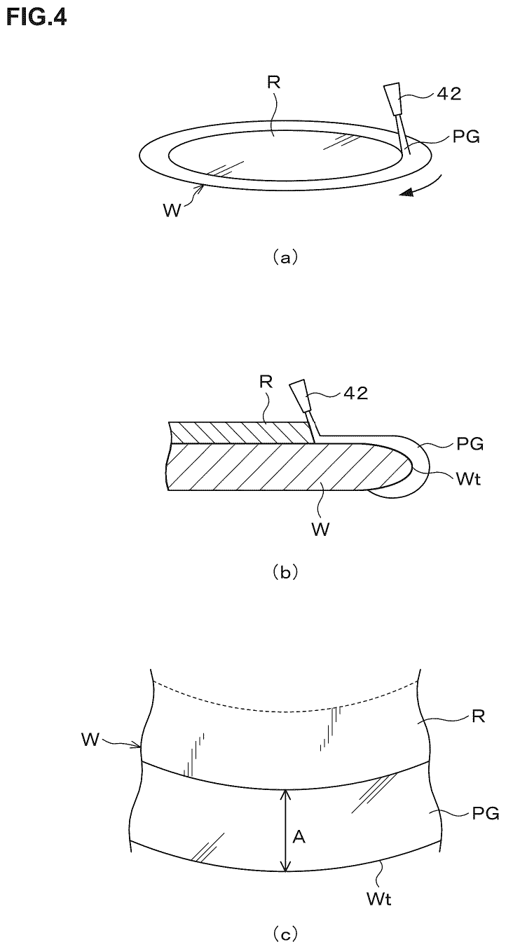

After the metal-containing resist film R is formed on the wafer W, the treatment solution supply nozzle 42 is then moved to near the end portion of the wafer Was illustrated in FIG. 4(a). Then, while the wafer W is being rotated, the solvent PG for the metal-containing resist solution is supplied to a region of a constant width A in the radial direction from the end portion Wt of the wafer Was illustrated also in FIG. 4(b) (c) to annularly remove the metal-containing resist film R in the region of the width A of the metal-containing resist film R. In this example, for the solvent PG, for example, PEGMEA is used. Further, the rotation speed of the wafer W at the first step is, for example, 1000 rpm.

Then, while the solvent PG is being supplied from the treatment solution supply nozzle 42 to the region of the width A on the front surface of the wafer W, the solvent PG is being supplied also from the first rear surface nozzle 51 to the peripheral portion on a rear surface of the wafer W. In this example, the solvent PG is PEGMEA.

### Second Step

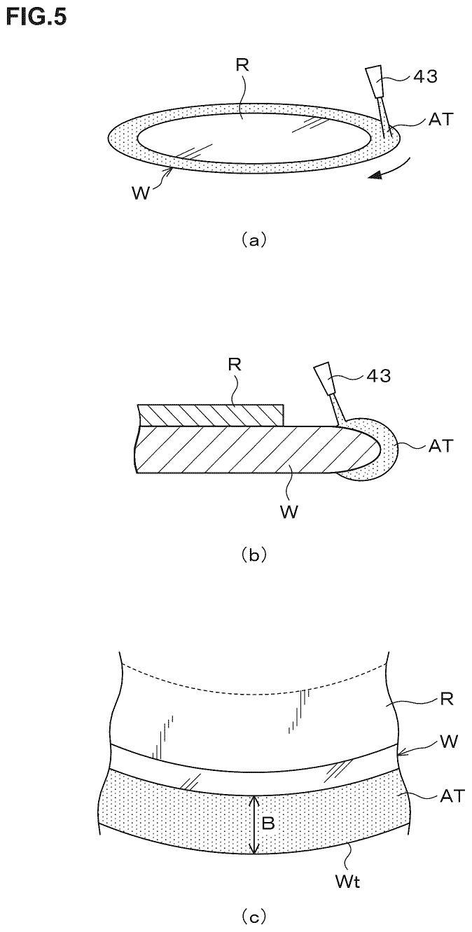

Next, as illustrated in FIG. 5(a), the treatment solution supply nozzle 43 in place of the treatment solution supply nozzle 42 is moved to near the end portion of the wafer W. Then, while the wafer W is being rotated, a treatment solution AT for dissolving the metal in the metal-containing resist film R is supplied to a region of a constant width B in the radial direction from the end portion Wt of the wafer Was illustrated also in FIG. 5(b), (c). This dissolves and removes the metal component temporarily remaining in the region of the width B. In this example, as the treatment solution AT for dissolving the metal, for example, the acid thinner is used as has been explained. Further, the rotation speed of the wafer W at the second step is, for example, 1000 rpm.

Then, while the acid thinner being the treatment solution AT is being supplied from the treatment solution supply nozzle 43 to the region of the width B on the front surface of the wafer W, the acid thinner being the treatment solution AT is being supplied also from the second rear surface nozzle 52 to the peripheral portion on the rear surface of the wafer W.

### Third Step

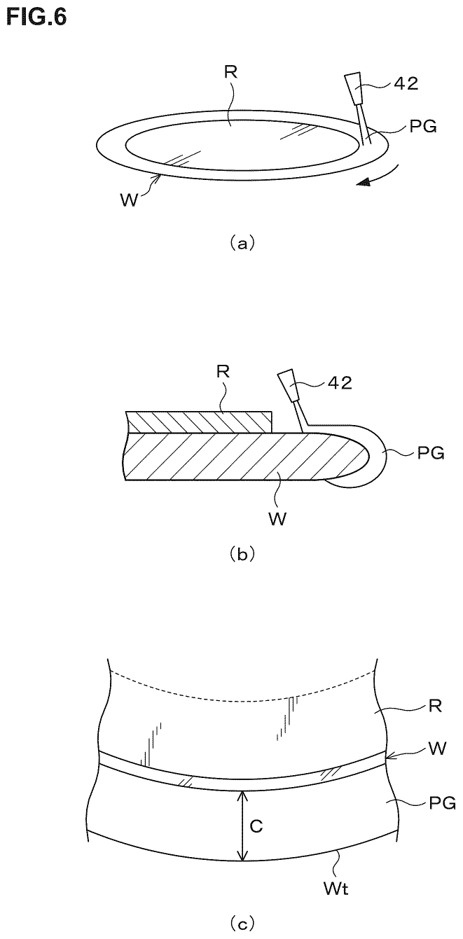

Then, as illustrated in FIG. 6(a), the treatment solution supply nozzle 42 in place of the treatment solution supply nozzle 43 is moved again to near the end portion of the wafer W. Then, while the wafer W is being rotated, the solvent PG for the metal-containing resist solution is supplied to a region of a constant width C in the radial direction from the end portion Wt of the wafer Was illustrated also in FIG. 6(b), (c). This washes away the acid thinner remaining in the region of the width C. In this example, the solvent PG is the already-explained PEGMEA. Further, the rotation speed of the wafer W at the third step is, for example, 1000 rpm.

Then, while the solvent PG is being supplied from the treatment solution supply nozzle 42 to the region of the width C on the front surface of the wafer W, the solvent PG is being supplied also from the first rear surface nozzle 51 to the peripheral portion on the rear surface of the wafer W.

The relation among lengths of the above width A, width B, and width C is A>C>B. According to the substrate treatment method according to the embodiment explained above, first, the first step annularly removes the region of the width A in the radial direction from the end portion Wt of the wafer W of the metal-containing resist film R formed on the front surface of the wafer W by the solvent PG. Then, the second step cleans the front surface of the wafer W in the region of the width B narrower than the width A by the acid thinner to dissolve and remove the metal component temporarily remaining in the region of the width B. Then, the third step cleans the front surface of the wafer W in the region of the width C wider than the region B and narrower than the width A by the solvent PG to wash away the acid thinner remaining in the region of the width C.

Accordingly, it is possible to suitably remove the peripheral portion of the metal-containing resist film R and suppress the occurrence of defects in the metal-containing coating and the base film on the front surface of the substrate in the removal of the peripheral portion of the metal-containing coating.

Further, in the above process, the reason why the relation among the lengths of the width A, width B, and width C is A>C>B is as follows. Specifically, at the first step, when the region of the width A of the metal-containing resist film R is dissolved and removed by the solvent PG, the metal component in components of the dissolved film may remain on the front surface of the wafer W after the removal of the film. If the metal component is left as it is, it adversely affects the subsequent process or become a cause of cross-contamination as has been already explained.

Therefore, it is necessary to remove the metal component which may remain on the front surface of the wafer W after the removal of the film. Hence, at the second step, for example, the acid thinner being a mixed solution of an acidic chemical agent and a thinner is supplied, as the treatment solution AT for dissolving the metal component is supplied to the front surface of the wafer W after the removal of the film. Thereafter, at the third step, the solvent PG is supplied to wash away the treatment solution AT.

Here, first of all, the reason why the width B of the region to which the treatment solution AT is supplied at the second step is narrower than the width A of the region to which the solvent PG is supplied at the first step is that with the width B =the width A, the treatment solution AT may penetrate into the metal-containing resist film R from the interface of the metal-containing resist film R removed by the solvent PG to corrode the metal-containing resist film R.

Besides, the reason why the width C of the region to which the solvent PG is supplied at the third step is wider than the width B of the region of the treatment solution AT supplied at the second step is to completely wash away the treatment solution AT supplied at the second step. Further, the reasons why the width C of the region to which the solvent PG is supplied at the third step is narrower than the width A of the region to which the solvent PG is supplied at the first step are, with the width C=the width A, the penetration of the washed away treatment solution AT from the interface of the metal-containing resist film R and flowing out the metal component in the metal-containing resist film R. From the above, the relation among the lengths of the above width A, width B, and width C is A>C>B in the above process.

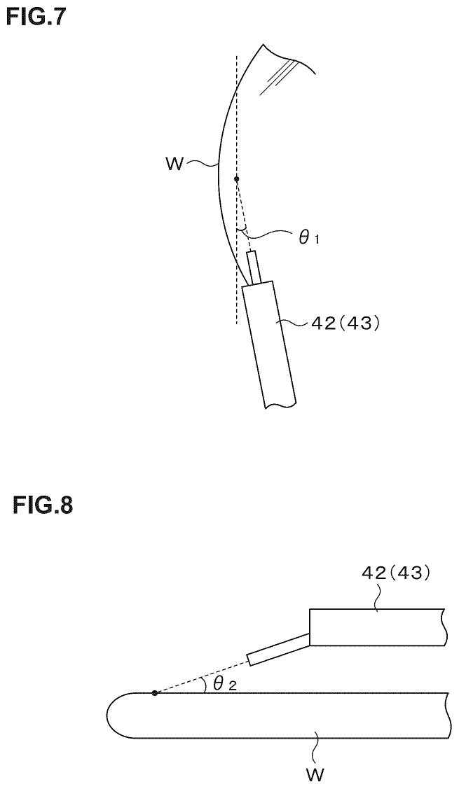

Here, explaining a discharge angle in plan view of the treatment solution supply nozzle 42, 43 to the wafer W, namely, an angle θ1 relative to the tangent of the wafer W illustrated in FIGS. 7, θ1 is set, for example, at 8.5 degrees for the treatment solution supply nozzle 42 which supplies the solvent PG. On the other hand, θ1 is set, for example, at 30 degrees for the treatment solution supply nozzle 43 which supplies the treatment solution AT for dissolving the metal component. Specifically, the treatment solution supply nozzle 43 which supplies the treatment solution AT is directed radially outward more than the treatment solution supply nozzle 42 which supplies the solvent PG. This is for suppressing splashing and scattering to the inner side of the supplied treatment solution AT, and for spreading, thereafter when washing away the treatment solution AT by the solvent PG, the solvent PG further inward.

Note that the discharge angle in side view of the treatment solution supply nozzle 42, 43 to the wafer W, namely, θ2 being a depression angle is set, for example, at 45 degrees for both the treatment solution supply nozzles 42, 43. The diagonal discharge as above prevents the supplied liquid from flowing to the direction of the center of the wafer W.

Since the treatment solution supply nozzle 43 for supplying the treatment solution AT is directed outward more than the treatment solution supply nozzle 42 for supplying the solvent PG, the treatment solution AT supplied from the treatment solution supply nozzle 43 is prevented from flowing to the center side of the wafer W and the solvent PG to be supplied at the third step thereafter can thoroughly clean away the previously supplied treatment solution AT.

The solvent PG used at the first step and the solvent PG used at the third step are the same solvent in the above embodiment, but the liquid to be supplied at the third step may be another solvent because the purpose of the solvent to be supplied at the third step is for washing away the treatment solution AT supplied at the second step. For example, it may be pure water. Since the solvent PG used at the first step and the solvent PG used at the third step are the same solvent in the above example, the shared treatment solution supply nozzle 42 can be used as nozzles for supply. However, in the case where the liquid to be supplied at the third step is liquid different from the solvent PG used at the first step, such as pure water, different nozzles need to be used as the supply nozzles. Specifically, the supply nozzles as the first treatment solution supplier, the second treatment solution supplier, and the third treatment solution supplier need to be separate ones.

In the above embodiment, all of the rotation speeds of the wafer W at the first step, the second step, and the third step are set to 1000 rpm, but the rotation speed may be made higher at the second step of supplying the treatment solution AT than at the first step and the third step of supplying the solvent PG. This is to suppress splashing of droplets of the treatment solution AT toward the region to which the solvent PG is to be supplied, when the treatment solution AT is supplied.

The solvent PG is supplied also from the first rear surface nozzle 51 on the rear surface side of the wafer W at the first step and the third step, and the treatment solution AT is supplied also from the second rear surface nozzle 52 at the second step. The liquid supplied from each of the rear surface nozzles is the same liquid as the liquid supplied from the front surface side of the wafer W. A purpose thereof is to prevent the liquid supplied to the front surface side of the wafer W from flowing around to the rear surface side of the wafer W. Accordingly, the positions of the first rear surface nozzle 51 and the second rear surface nozzle 52 arranged on the rear surface side do not need to be set so strictly as those of the treatment solution supply nozzles 42, 43 arranged on the front surface side of the wafer W.

However, from the viewpoint of preventing the liquid supplied to the front surface side of the wafer W from flowing around to the rear surface side of the wafer W, the positions of the first rear surface nozzle 51 and the second rear surface nozzle 52 arranged on the rear surface side are preferably set at positions opposed, across the wafer W, to the treatment solution supply nozzles 42, 43 arrange on the front surface side of the wafer W. In this case, the positions in the radial direction of the first rear surface nozzle 51 and the second rear surface nozzle 52 arranged on the rear surface side are preferably positions on the inner side of the treatment solution supply nozzles 42, 43 arranged on the front surface side of the wafer W, namely, positions closer to the center of the wafer W.

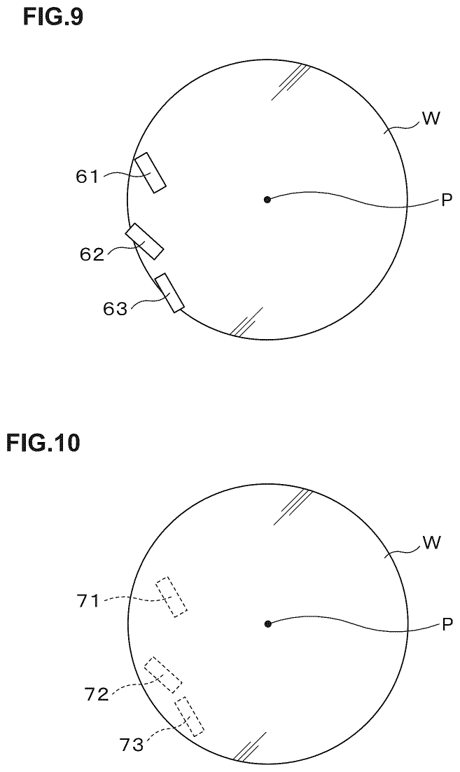

FIG. 9 schematically illustrates in plan view an arrangement situation when the supply nozzles as the first treatment solution supplier, the second treatment solution supplier, and the third treatment solution supplier are made as separate nozzles and arranged on the front surface side of the wafer W as treatment solution supply nozzles 61, 62, 63. Besides, FIG. 10 schematically illustrates in plan view the arrangement situation of rear surface nozzles 71, 72, 73 arranged on the rear surface side in that case. Note that the illustration of the treatment solution supply nozzles 61, 62, 63 on the front surface side is omitted in FIG. 10 for convenience of illustration.

As is clear from FIG. 9 and FIG. 10, the rear surface nozzles 71, 72, 73 arranged on the rear surface side are located at positions opposed, across the wafer W, to the treatment solution supply nozzles 61, 62, 63 arranged on the front surface side, but the positions in the radial direction of the rear surface nozzles 71, 72, 73 are set positions closer to the center P of the wafer W than those of the treatment solution supply nozzles 61, 62, 63 arranged on the front surface side. This can more surely prevent the liquid supplied from the treatment solution supply nozzles 61, 62, 63 to the front surface side of the wafer W from flowing around to the rear surface side of the wafer W.

The basic substrate treatment is completed by the first step→the second step→the third step in the above embodiment but, not limited to this, may be completed, for example, by execution of the first step→the second step→the third step and then the second step→the third step again. In other words, the second step and the third step may be repeatedly performed. This can perform a suitable treatment according to the remaining situation of the metal component and the treatment solution AT such as the acid thinner remaining on the front surface of the substrate.

Besides, the above coating film forming apparatus 1 is configured to perform the treatment of forming the metal-containing resist film R on the wafer W and the first step, the second step, and the third step of removing the peripheral portion of the metal-containing resist film R in the same apparatus but, not limited to this, may perform the treatment of forming the metal-containing resist film R and the treatments at the first step to the third step in different apparatuses and modules.

The embodiments disclosed herein are examples in all respects and should not be considered to be restrictive. Various omissions, substitutions, and changes may be made in the embodiments without departing from the scope and the spirit of the attached claims.

Note that the following configurations also belong to the technical scope of this disclosure.

(1) A substrate treatment apparatus for treating a substrate, the apparatus including:
a substrate holder configured to hold and rotate a substrate on which a coating film containing metal is formed;
a first treatment solution supplier configured to supply a first treatment solution to a front surface of the substrate;
a second treatment solution supplier configured to supply a second treatment solution to the front surface of the substrate;
a third treatment solution supplier configured to supply a third treatment solution to the front surface of the substrate; and
a controller, wherein
the controller is configured to execute:
   a first step of supplying the first treatment solution from the first treatment solution supplier to a first width region from an end portion of the substrate while rotating the substrate to remove the coating film;
   a second step of supplying, after the first step, the second treatment solution from the second treatment solution supplier to a second width region having a width narrower than the first width region from the end portion of the substrate while rotating the substrate to remove the metal remaining in the second width region; and
   a third step of supplying, after the second step, the third treatment solution from the third treatment solution supplier to a third width region having a width narrower than the first width region and wider than the second width region from the end portion of the substrate while rotating the substrate to wash away the second treatment solution remaining in the third width region.

(2) The substrate treatment apparatus according to (1), wherein the first treatment solution and the third treatment solution are a same treatment solution.

(3) The substrate treatment apparatus according to (1), wherein the first treatment solution and the third treatment solution are organic solvents.

(4) The substrate treatment apparatus according to (2), wherein
the first treatment solution supplier and the third treatment solution supplier are shared.

(5) The substrate treatment apparatus according to any one of (1) to (4), wherein
the second treatment solution is an acidic treatment solution for dissolving the metal.

(6) The substrate treatment apparatus according to (1), wherein:
the first treatment solution is an organic solvent; and
the third treatment solution is pure water.

(7) The substrate treatment apparatus according to (6), wherein the second treatment solution is an acidic treatment solution for dissolving the metal.

(8) The substrate treatment apparatus according to (6), further including
a coating solution supplier configured to supply a coating solution containing metal to the substrate held on the substrate holder, wherein
the controller is configured to supply, before the first step, the coating solution from the coating solution supplier to the front surface of the substrate held on the substrate holder to execute the step of forming the coating film.

(9) The substrate treatment apparatus according to (7), further including
a fourth treatment solution supplier configured to supply a second treatment solution to a rear surface of the substrate, wherein
when the second treatment solution is being supplied from the second treatment solution supplier at the second step, the fourth treatment solution supplier supplies the second treatment solution.

(10) The substrate treatment apparatus according to (9), further including
a fifth treatment solution supplier configured to supply a third treatment solution to the rear surface of the substrate, wherein
when the third treatment solution is being supplied from the third treatment solution supplier at the third step, the fifth treatment solution supplier supplies the third treatment solution.

(11) The substrate treatment apparatus according to (1), wherein
a rotation speed of the substrate at the second step is higher than rotation speeds of the substrate at the first step and the third step.

(12) The substrate treatment apparatus according to (1), wherein
a discharge angle relative to a tangent of the substrate in plan view when the second treatment solution is supplied from a nozzle as the second treatment solution supplier is directed radially outward more than a discharge angle when the first treatment solution is supplied from a nozzle as the first treatment solution supplier.

(13) The substrate treatment apparatus according to (12), wherein
a rotation speed of the substrate at the second step is higher than a rotation speed of the substrate at the first step.

(14) The substrate treatment apparatus according to (1), wherein
a rotation speed of the substrate at the second step is higher than a rotation speed of the substrate at the first step.

(15) The substrate treatment apparatus according to (1), wherein
after executing the third step, the controller executes the second step and the third step again.

(16) A substrate treatment method for treating a substrate, the method including:
a first step of supplying a first treatment solution to a first width region from an end portion of the substrate while rotating the substrate to remove a coating film in the first width region;
a second step of supplying, after the first step, a second treatment solution to a second width region having a width narrower than the first width region from the end portion of the substrate while rotating the substrate to remove a metal component remaining in the second width region; and
a third step of supplying, after the second step, a third treatment solution to a third width region having a width narrower than the first width region and wider than the second width region from the end portion of the substrate while rotating the substrate to wash away the second treatment solution remaining in the third width region.

(17) The substrate treatment method according to (16), wherein
the first treatment solution and the third treatment solution are a same treatment solution.

(18) The substrate treatment method according to (16) wherein
the first treatment solution and the third treatment solution are organic solvents.

(19) The substrate treatment method according to any one of (16) to (18), wherein
the second treatment solution is an acidic treatment solution for dissolving the metal component.

(20) The substrate treatment method according to (16), wherein
the first treatment solution is an organic solvent, and the third treatment solution is pure water.

(21) The substrate treatment method according to (20), wherein
the second treatment solution is an acidic treatment solution for dissolving the metal component.

(22) The substrate treatment method according to (21), wherein
when the second treatment solution is being supplied at the second step, the second treatment solution is supplied from a rear surface of the substrate.

(23) The substrate treatment method according to (22), wherein when the third treatment solution is being supplied at the third step, the third treatment solution is supplied from the rear surface of the substrate.

(24) The substrate treatment method according to claim (16), wherein
a rotation speed of the substrate at the second step is higher than rotation speeds of the substrate at the first and third steps.

(25) The substrate treatment method according to (16), wherein
a discharge angle relative to a tangent of the substrate in plan view when the second treatment solution is supplied from a nozzle is directed radially outward more than a discharge angle when the first treatment solution is supplied from a nozzle.

(26) The substrate treatment method according to (16), wherein
a rotation speed of the substrate at the second step is higher than a rotation speed of the substrate at the first step.

(27) The substrate treatment method according to (25), wherein
a rotation speed of the substrate at the second step is higher than a rotation speed of the substrate at the first step.

(28) The substrate treatment method according to (16), wherein
after the third step is executed, the second step and the third step are executed again.

### EXPLANATION OF CODES

1 coating film forming apparatus
2 treatment container
11 spin chuck
42 treatment solution supply nozzle
43 treatment solution supply nozzle
100 controller
R metal-containing resist film
W wafer
Wt end portion

1. A substrate treatment apparatus for treating a substrate, the apparatus comprising:
a substrate holder configured to hold and rotate a substrate on which a coating film containing metal is formed;
a first treatment solution supplier configured to supply a first treatment solution to a front surface of the substrate;
a second treatment solution supplier configured to supply a second treatment solution to the front surface of the substrate;
a third treatment solution supplier configured to supply a third treatment solution to the front surface of the substrate; and
a controller, wherein
the controller is configured to execute:
a first step of supplying the first treatment solution from the first treatment solution supplier to a first width region from an end portion of the substrate while rotating the substrate to remove the coating film;
a second step of supplying, after the first step, the second treatment solution from the second treatment solution supplier to a second width region having a width narrower than the first width region from the end portion of the substrate while rotating the substrate to remove the metal remaining in the second width region; and
a third step of supplying, after the second step, the third treatment solution from the third treatment solution supplier to a third width region having a width narrower than the first width region and wider than the second width region from the end portion of the substrate while rotating the substrate to wash away the second treatment solution remaining in the third width region.

2. The substrate treatment apparatus according to claim 1, wherein
the first treatment solution and the third treatment solution are a same treatment solution.

3. The substrate treatment apparatus according to claim 1, wherein
the first treatment solution and the third treatment solution are organic solvents.

4. The substrate treatment apparatus according to claim 2, wherein
the first treatment solution supplier and the third treatment solution supplier are shared.

5. The substrate treatment apparatus according to claim 1, wherein
the second treatment solution is an acidic treatment solution for dissolving the metal.

6. (canceled)

7. (canceled)

8. (canceled)

9. (canceled)

10. (canceled)

11. The substrate treatment apparatus according to claim 1, wherein
a rotation speed of the substrate at the second step is higher than rotation speeds of the substrate at the first and third steps.

12. The substrate treatment apparatus according to claim 1, wherein
a discharge angle relative to a tangent of the substrate in plan view when the second treatment solution is supplied from a nozzle as the second treatment solution supplier is directed radially outward more than a discharge angle when the first treatment solution is supplied from a nozzle as the first treatment solution supplier.

13. The substrate treatment apparatus according to claim 12, wherein
a rotation speed of the substrate at the second step is higher than a rotation speed of the substrate at the first step.

14. The substrate treatment apparatus according to claim 1, wherein
a rotation speed of the substrate at the second step is higher than a rotation speed of the substrate at the first step.

15. The substrate treatment apparatus according to claim 1, wherein
after executing the third step, the controller executes the second step and the third step again.

16. A substrate treatment method for treating a substrate, the method comprising:
a first step of supplying a first treatment solution to a first width region from an end portion of the substrate while rotating the substrate to remove a coating film in the first width region;
a second step of supplying, after the first step, a second treatment solution to a second width region having a width narrower than the first width region from the end portion of the substrate while rotating the substrate to remove a metal component remaining in the second width region; and
a third step of supplying, after the second step, a third treatment solution to a third width region having a width narrower than the first width region and wider than the second width region from the end portion of the substrate while rotating the substrate to wash away the second treatment solution remaining in the third width region.

17. The substrate treatment method according to claim 16, wherein
the first treatment solution and the third treatment solution are a same treatment solution.

18. The substrate treatment method according to claim 16, wherein
the first treatment solution and the third treatment solution are organic solvents.

19. The substrate treatment method according to claim 1, wherein
the second treatment solution is an acidic treatment solution for dissolving the metal component.

20. (canceled)

21. (canceled)

22. (canceled)

23. (canceled)

24. The substrate treatment method according to claim 16, wherein
a rotation speed of the substrate at the second step is higher than rotation speeds of the substrate at the first step and the third step.

25. The substrate treatment method according to claim 16, wherein
a discharge angle relative to a tangent of the substrate in plan view when the second treatment solution is supplied from a nozzle is directed radially outward more than a discharge angle when the first treatment solution is supplied from a nozzle.

26. The substrate treatment method according to claim 16, wherein
a rotation speed of the substrate at the second step is higher than a rotation speed of the substrate at the first step.

27. The substrate treatment method according to claim 25, wherein
a rotation speed of the substrate at the second step is higher than a rotation speed of the substrate at the first step.

28. The substrate treatment method according to claim 16, wherein
after the third step is executed, the second step and the third step are executed again.
